(19) United States
(12) Patent Application Publication
(10) Pub. No.: US 2023/0018448 A1
(43) Pub. Date: Jan. 19, 2023

(54) REDUCED IMPEDANCE SUBSTRATE

(71) Applicant: QUALCOMM Incorporated, San Diego, CA (US)

(72) Inventors: Aniket PATIL, San Diego, CA (US); Joan Rey Villarba BUOT, Escondido, CA (US); Hong Bok WE, San Diego, CA (US)

(21) Appl. No.: 17/375,676

(22) Filed: Jul. 14, 2021

(51) Int. Cl. H01L 23/48; H01L 25/065; H01L 23/532; H01L 23/528; H01L 21/768; H01L 27/108

(52) U.S. Cl. CPC H01L 23/481; H01L 25/0657; H01L 23/53209; H01L 23/5286; H01L 21/76898; H01L 27/108; H01L 2225/0652; H01L 2225/06548

(57) ABSTRACT

Disclosed are apparatus comprising a substrate and techniques for fabricating the same. The substrate may include a first metal layer having signal interconnects on a first side of the substrate. A second metal layer may include ground plane portions on a second side of the substrate. Conductive channels may be formed in the substrate and coupled to the ground plane portions. The conductive channels are configured to extend the ground plane portions towards the signal interconnects to reduce a distance from individual signal interconnects to individual conductive channels. The distance may be in a range of seventy-five percent to fifty percent of a substrate thickness between the first metal layer and the second metal layer.

### BACKGROUND OF THE DISCLOSURE

### 1. Field of the Disclosure

Aspects of this disclosure relate generally to an integrated circuit (IC), and particularly to reducing an impedance on a substrate for high-speed data signals.

### 2. Description of the Related Art

A semiconductor (also known as a chip or integrated circuit (IC)), may include a Molded Embedded Package (MEP) with a stacked substrate. The MEP may include package-on-package (POP) with connections for dynamic random-access memory (DRAM). In conventional designs, substrates that form connections between memory (e.g., DRAM) and processors can be limited by high impedance of the signal interconnects coupling the memory to the processor.

Accordingly, there is a need for systems, apparatuses and methods that overcome the deficiencies of conventional substrate designs including the methods, systems and apparatuses provided herein in the following disclosure.

### SUMMARY

The following presents a simplified summary relating to one or more aspects disclosed herein. As such, the following summary should not be considered an extensive overview relating to all contemplated aspects, nor should the following summary be regarded to identify key or critical elements relating to all contemplated aspects or to delineate the scope associated with any particular aspect. Accordingly, the following summary has the sole purpose to present certain concepts relating to one or more aspects relating to the mechanisms disclosed herein in a simplified form to precede the detailed description presented below.

In at least one aspect includes an apparatus comprising a substrate. The substrate comprises: a first metal layer comprising a plurality of signal interconnects on a first side of the substrate; a second metal layer comprising a plurality of ground plane portions on a second side of the substrate; and a plurality of conductive channels in the substrate coupled to the plurality of ground plane portions configured to extend the plurality of ground plane portions towards the signal interconnects to reduce a distance from individual signal interconnects to individual conductive channels, and wherein the distance is in a range of seventy-five percent to fifty percent of a substrate thickness between the first metal layer and the second metal layer.

At least one other second aspect includes a method of fabricating an apparatus. The method comprises: providing a substrate comprising a first metal layer and a second metal layer; forming a plurality of signal interconnects on a first side of the substrate; forming a plurality of ground plane portions on a second side of the substrate; and forming a plurality of conductive channels in the substrate coupled to the plurality of ground plane portions configured to extend the plurality of ground plane portions towards the signal interconnects to reduce a distance from individual signal interconnects to individual conductive channels, and wherein the distance is in a range of seventy-five percent to fifty percent of a substrate thickness between the first metal layer and the second metal layer.

Other objects and advantages associated with the aspects disclosed herein will be apparent to those skilled in the art based on the accompanying drawings and detailed description.

### BRIEF DESCRIPTION OF THE DRAWINGS

The accompanying drawings are presented to aid in the description of various aspects of the disclosure and are provided solely for illustration of the aspects and not limitation thereof. A more complete understanding of the present disclosure may be obtained by reference to the following Detailed Description when taken in conjunction with the accompanying Drawings. In the figures, the left-most digit(s) of a reference number identifies the figure in which the reference number first appears. The same reference numbers in different figures indicate similar or identical items.

FIG. 1 illustrates an exemplary package having a core, according to various aspects of the disclosure.

FIG. 2 illustrates an exemplary coreless package, according to various aspects of the disclosure.

FIG. 3 illustrates an exemplary package that includes a Molded Embedded Package (MEP) with a stacked substrate, according to various aspects of the disclosure.

FIGS. 4A, 4B, 4C, and 4D illustrate a first set of stages to form a cored substrate of a package, according to various aspects of the disclosure.

FIGS. 5A, 5B, 5C, and 5D illustrate a second set of stages to form a cored substrate of a package, according to various aspects of the disclosure.

FIG. 6 illustrates a process that includes forming a cored substrate of a package, according to various aspects of the disclosure.

FIG. 7 illustrates various electronic devices that may be integrated with an integrated device or a semiconductor device in accordance with one or more aspects of the disclosure.

### DETAILED DESCRIPTION

Aspects of the disclosure are provided in the following description and related drawings directed to various examples provided for illustration purposes. Alternate aspects may be devised without departing from the scope of the disclosure. Additionally, well-known elements of the disclosure will not be described in detail or will be omitted so as not to obscure the relevant details of the disclosure.

The words “example” and/or “example” are used herein to mean “serving as an example, instance, or illustration.” Any aspect described herein as “example” and/or “example” is not necessarily to be construed as preferred or advantageous over other aspects. Likewise, the term “aspects of the disclosure” does not require that all aspects of the disclosure include the discussed feature, advantage, or mode of operation.

The various aspects disclosed herein include devices and techniques to reduce an impedance of a substrate (cored or coreless) to enable the use of high-speed signals, e.g., signals sent at between about 200 Mega Hertz (MHz) to 12 Giga Hertz (GHz). In some aspects, the high-speed signals may include high-speed data (DQ) signals used to access Dynamic Random-Access Memory (DRAM). For example, package-on-package (POP) DRAM uses high speed DQ signals for data transfer to and from the memory arrays. The various aspects disclosed herein include devices and techniques for controlling impedance in a substrate to facilitate high speed communications.

The devices and techniques described herein may be used with packages having a cored substrate or a coreless substrate (e.g., pre-preg). The fiberglass that is pre-impregnated with resin is referred to as pre-preg. The core in a cored substrate may be formed using, for example, copper clad lamination (CCL), e.g., copper with epoxy material reinforced with fiberglass. The copper clad laminate is soaked in resin with the fiberglass (or other reinforcing material) and copper cladding is added on either one side or both sides. In some example aspects, the core thickness may range from 40 micrometers (um or microns) to 1.2 millimeters (mm).

In some aspects, a semiconductor (also known as a chip or integrated circuit (IC)), may include a Molded Embedded Package (MEP) with a stacked substrate. The MEP may include a package-on-package (POP) with connections for dynamic random-access memory (DRAM). In some aspects, the MEP uses a two-layer substrate, with a first layer (M1) used for signal routing and a second layer (M2) used generally as a ground shield plane. For example, when the thickness of the cored substrate is typically about 40 micrometers (μm or microns), the cored substrate may have an impedance of at least 50 Ohms (a). Such a relatively high impedance may affect the speed of signals in the signal routing.

For high-speed signals, an impedance lower than 50 ohms is preferred, particularly as DRAM access speeds increase. One way to lower impedance is to decrease the distance between the high-speed signals (e.g., a first layer) and the ground plane (e.g., a second layer). However, for a cored substrate that is about 40 microns thick, using a thinner core may not be an option because the thinner core may result in warpage. The devices and techniques described herein can be used to reduce impedance by decreasing the distance between the high-speed signals (e.g., the first layer) and the ground plane (e.g., the second layer) without changing the thickness of the substrate. It will be appreciated that the various aspects are not limited to the foregoing example configurations. For example, in some configurations the layers may be reversed, some signals and/or power lines may be included in the M2 layer, the core may be of a different thickness, etc.

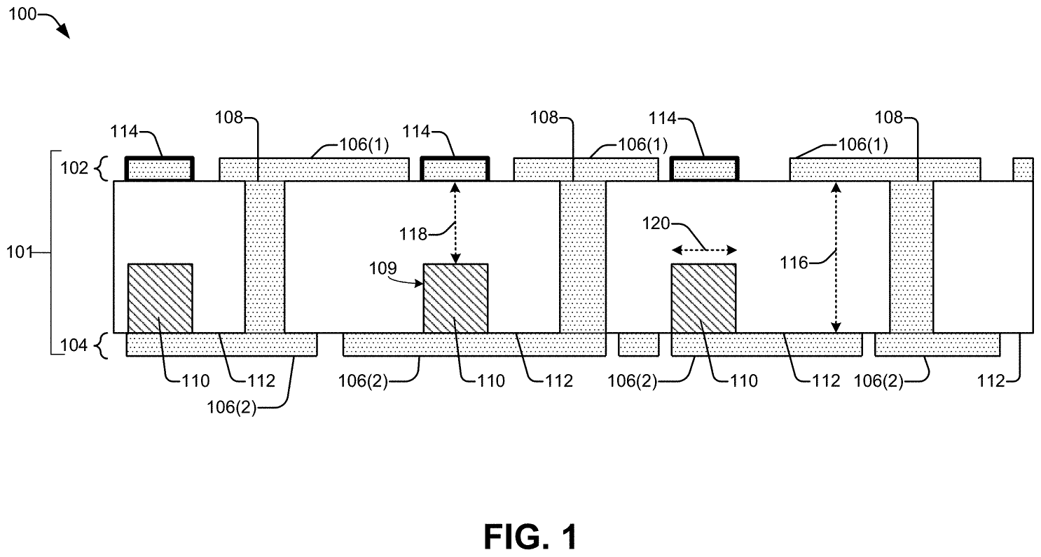

FIG. 1 illustrates an exemplary package 100 having a cored substrate 101, according to various aspects of the disclosure. The package 100 includes a cored substrate 101 having a core 112, a first metal layer 102 (also referred to as M1) above a core 112 and a second metal layer 104 (also referred to as M2) below the core 112.

The first metal layer 102 may include structures such as signal interconnects 114 the signal interconnects may be traces or lines in the first metal layer. The first metal layer includes a plurality of signal interconnects, and other metal structures, such as adjacent grounds 106(1), pads and the like. The second metal layer 104 may include ground plane portions 106(2), which may be opposite the signal interconnects 114. The ground plane portions 106(2) are coupled to a ground potential and collectively form a ground reference plane. Vias 108 may be plated or filled through substrate vias and may be configured to electrically couple the adjacent grounds 106(1) in the first metal layer 102 to the ground plane portions 106(2) in the second metal layer 104. It will be appreciated that in various aspects, the metal planes 106 may be coupled to a power line (Vdd) or a ground, the metal planes 106 illustrated in FIG. 1 are to be understood as being ground plane portions.

Conductive channels 110 are located in a core 112 of the cored substrate 101. Although one metal layer (e.g., 102, 104) is illustrated, it will be appreciated that the various aspects disclosed are not limited to this configuration. In some aspects, the cored substrate 101 may have more than one metal layer on each side of the core 112. In some aspects, as illustrated in FIG. 1, the first metal layer 102 (M1), the plated through vias 108, conductive channels 110 and the second metal layer 104 (M2) may use any highly conductive material, such as, for example, Copper (Cu), Cobalt (Co), Ruthenium (Ru), Tungsten (W), Molybdenum (Mo), Gold (Au), Silver (Ag), Aluminum (Al), Tin (Sn), or any combination thereof.

In the example illustrated in FIG. 1, each conductive channel 110 is located below and generally aligned with each of the signal interconnects 114. The conductive channel is formed in a trench 109, which is illustrated only as a boundary of the conductive channel 110. The signal interconnects 114 can be configured to carry high speed signals. In some aspects, the high-speed signals may include DQ (data) signals for dynamic random-access memory (DRAM). In some aspects, the core 112 has a thickness 116 (e.g., substrate thickness) of about 40 microns. In some aspects, each conductive channel 110 has a channel width 120 approximately the same width as each signal interconnect 114 to about 5 microns wider than each signal interconnect 114. The extra width may be used to compensate for slight misalignment between the signal interconnects 114 and the conductive channels 110. As discussed herein, the addition of the conductive channels 110 that are electrically coupled to the ground plane portions 106(2) result in an effective reduction in the distance 118 between the signal interconnects 114 and the ground plane portions 106(2). Additionally, in the portions below the signal interconnects 114 the core 112 is reduced from a thickness 116 to the distance 118. The distance 118 is between about 25% to 50% less than the thickness 116 or can be considered to be 75% to 50% (i.e., reduced by 25% to 50%) of the substrate thickness between the first metal layer 102 and the second metal layer 104. For example, when the thickness 116 is about 40 microns, the distance 118 may be between about 20 to 30 microns or generally less than about 30 microns.

In some aspects, the substrate 101 may be a printed circuit board (PCB) and may include prepreg and the core 112. The core 112 may use a pre-preg, such as FR4, where FR indicates a flame-retardant material and ‘4’ indicates woven glass reinforced epoxy resin, and has a uniform, specified thickness (e.g., 40 microns). The core 112 is used to provide structural stability (e.g., prevent warpage, deformation, etc.), with signals travelling on the signal interconnects 114 on the first layer 102 and a ground plane on the second layer 104. The uniform thickness of the core 112 creates a uniform impedance. The conductive channels 110 are able to lower the impedance without decreasing the thickness 116 of the core 112 or substantially decreasing the structural stability.

The conductive channels 110 are electrically coupled to the ground plane portions 106(2) and are formed in the core 112, beneath signal interconnects 114 configured to carry high-speed data. This configuration provides a technical advantage of effectively reducing the distance between the signal interconnects 114 and the ground plane portions 106(2), via the conductive channels 110. The reduced distance 118 provides a for a lower impedance, as discussed herein. The lower impedance provides the technical advantage of enabling the signal interconnects 114 to be configured to carry high-speed data signals, such as DQ signals used to access DRAM. In this way, the signal interconnects 114 can be used to access faster DRAM (e.g., as compared to substrates that do not include the conductive channels), which provides improved performance for a given substrate design.

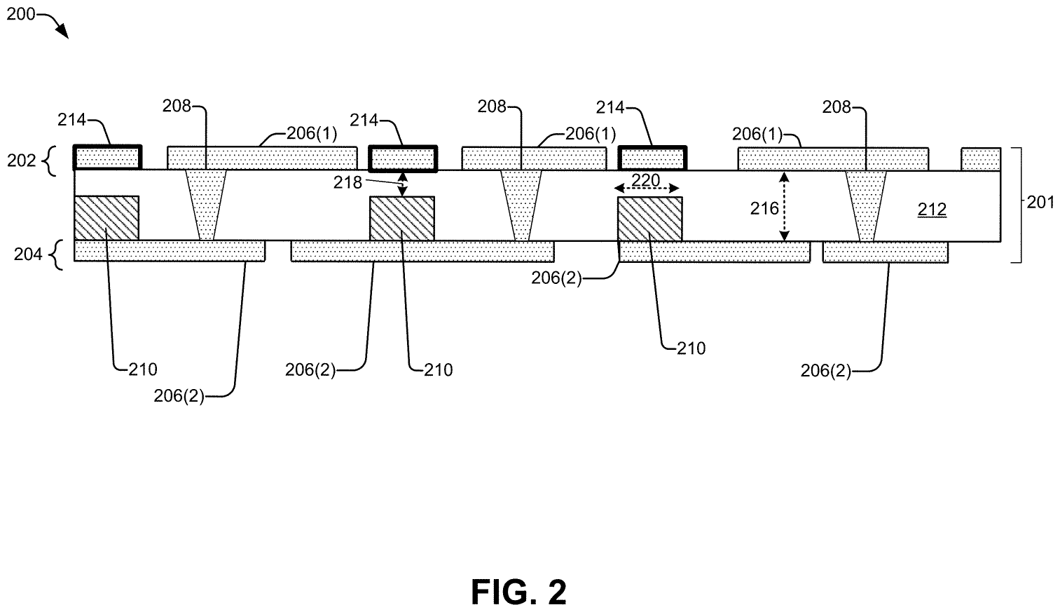

In accordance with the various aspects disclosed, the devices and techniques described herein may also be used with a coreless substrate. FIG. 2 illustrates an exemplary coreless substrate 201 of a package 200, according to various aspects of the disclosure. The package 200 includes a coreless substrate 201 having a dielectric 212, a first metal layer 202 (also referred to as M1) above the dielectric 212 and a second metal layer 204 (also referred to as M2) below the dielectric 212.

The first metal layer 202 may include structures such as signal interconnects 214 and other metal structures, such as adjacent grounds 206(1). The second metal layer 204 may include ground plane portions 206(2), which may be opposite the signal interconnects 214. The ground plane portions 206(2) are coupled to a ground potential. Vias 208 may connect the adjacent grounds 206(1) in the first metal layer 202 to the ground plane portions 206(2) in the second metal layer 204.

Conductive channels 210 are located in the dielectric 212 of the coreless substrate 201. Although one metal layer (e.g., 202, 204) is illustrated, it will be appreciated that the various aspects disclosed are not limited to this configuration. In some aspects, the coreless substrate 201 may have more than one metal layer on each side of the dielectric 212. In some aspects, as illustrated in FIG. 2, the first metal layer 202 (M1), the vias 208, conductive channels 210 and the second metal layer 204 (M2) may use any highly conductive material, such as, for example, Copper (Cu), Cobalt (Co), Ruthenium (Ru), Tungsten (W), Molybdenum (Mo), Gold (Au), Silver (Ag), Aluminum (Al), Tin (Sn), or any combination thereof.

In the example illustrated in FIG. 2, each conductive channel 210 is located below and generally aligned with each of the signal interconnects 214. The signal interconnects 214 can be configured to carry high speed signals. In some aspects, the high-speed signals may include DQ (data) signals for dynamic random-access memory (DRAM). In some aspects, each conductive channel 210 has a channel width 220 approximately the same width as each signal interconnect 214 to about 5 microns wider than each signal interconnect 214. The extra width may be used to compensate for slight misalignment between the signal interconnects 214 and the conductive channels 210. As discussed herein, the addition of the conductive channels 210 that are electrically coupled to the ground plane portions 206(2) result in an effective reduction in the distance 218 between the signal interconnects 214 and the ground plane portions 206(2). Additionally, in the portions below the signal interconnects 214 the dielectric 212 is reduced from a thickness 216 (substrate thickness) to the distance 218. The distance 218 is between about 25% to 50% less than the thickness 216 or 75% to 50% of the thickness 216. For example, when the thickness 216 is about 25 microns, the distance 218 may be between about 12.5 to 19 microns.

A thickness 216 of the coreless substrate 201 may be between about 25 microns to 50 microns. The coreless substrate 201, in some aspects, may include one or more layers of a dielectric 212. In some aspects, the dielectric 212 may be a pre-preg having a thickness of between about 25 microns to 50 microns. A width 220 of the conductive channels 210 may be between about 8 um to 100 um and in some aspects may be in the range of 25% to 75% of the substrate thickness. In some aspects, the conductive channel 210 may have a depth of about 12 microns and be located in the dielectric 212 to lower the impedance of the signal interconnects 214, in a similar fashion as discussed above in relation to the cored substrate discussed above.

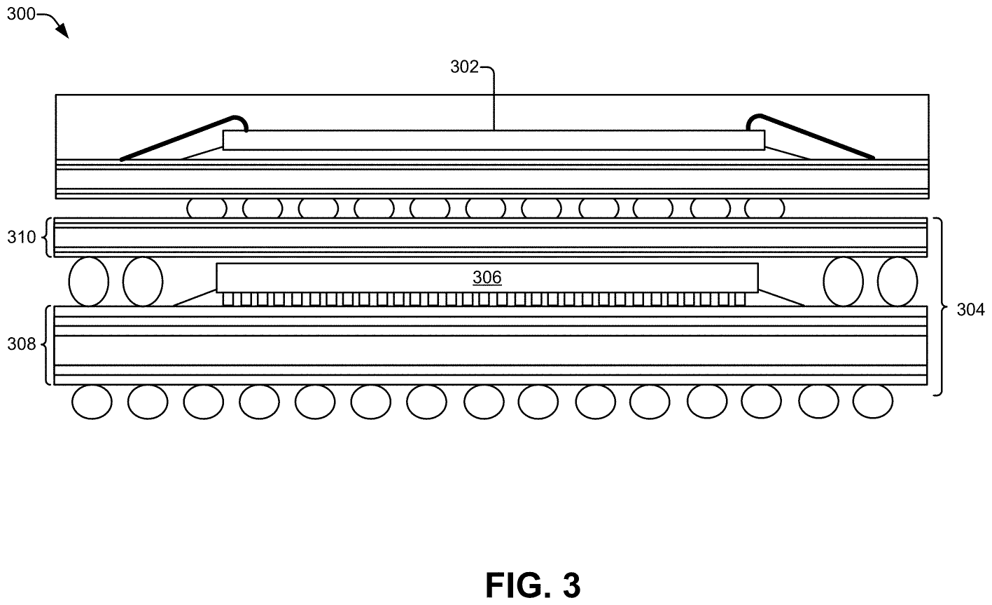

FIG. 3 illustrates an exemplary package 300 that includes a molded embedded package (MEP) 304 with a stacked substrate, according to various aspects of the disclosure. The package 300 includes a dynamic random-access memory (DRAM) 302 electrically coupled to an MEP 304. The MEP 304 includes a substrate 310, an application processor (AP) die 306, and a package substrate 308. In some aspects the substrate 310 may be configured as interposer to couple the AP die 306 to the DRAM 302 and may be designed in accordance with cored substrate 101 of FIG. 1 or the coreless substrate 201 of FIG. 2. It will be appreciated that the illustrated arrangement is provided merely as an example configuration to aid in illustration of the various aspects disclosed herein and other configurations are included within the various aspects disclosed. For example, the AP die 306 could be a standalone device, not part of MEP 304 and still utilize the substrate 310 to couple to the DRAM 302. Accordingly, the various aspects disclosed should not be construed to be limited to the illustrated example and other arrangements and configurations of the various components will be apparent from the disclosure herein.

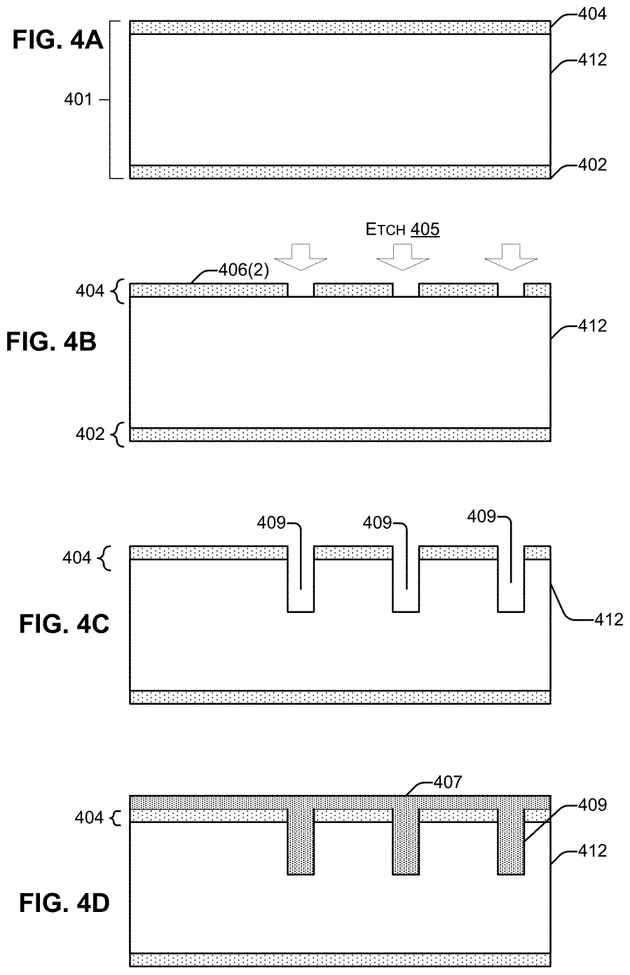

FIGS. 4A, 4B, 4C, and 4D illustrate a partial fabrication process, according to one or more aspects of the disclosure. In FIG. 4A, the fabrication process may begin by providing a copper core laminate (CCL) substrate 401 that includes a first metal layer 402, a second metal layer 404 and the core 412 (e.g., FR4). In FIG. 4B, the fabrication process may continue with a patterning and etch 405 being performed on the second metal layer 404 to form metal openings in the second metal layer 404 to expose the core 412. Further, in some aspects the etch 405 may also form other metal structures in the second metal layer 404. In FIG. 4C, the fabrication process may continue with the patterning of trenches 409 in the core 412 through the openings in the second metal layer 404. In FIG. 4D, the fabrication process may continue with a layer of photoresist 407 being applied to the second metal layer 404, where the etch 405 was performed. The layer of photoresist 407 may also fill the trenches 409 though the opening in the second metal layer 404.

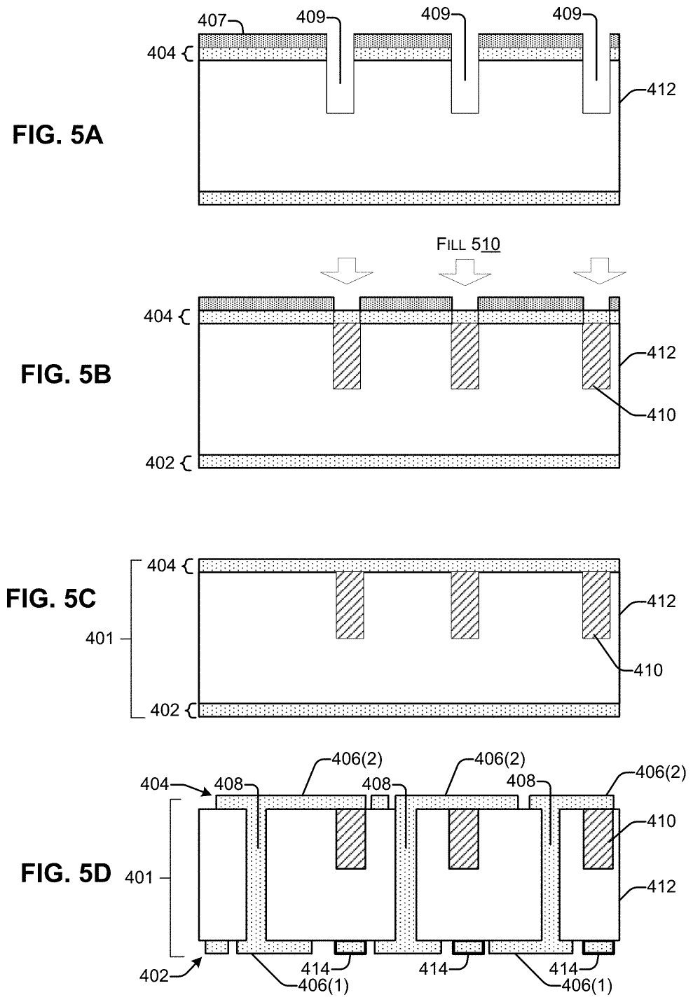

FIGS. 5A, 5B, 5C, and 5D illustrate a partial fabrication process, according to one or more aspects of the disclosure. In FIG. 5A, the fabrication process may continue from FIG. 4D with the photoresist 407 being removed from the trenches 409 and the openings in the second metal layer 404. In FIG. 5B, the fabrication process continues with a metal fill process 510. The metal may be copper or the like and is used to fill each of the trenches 409 to create the conductive channels 410. In addition to forming the conductive channels, 410, the metal filling process 510 may fill in the openings in the second metal layer 404. It will be appreciated that the conductive channels 410 are closer to the first metal layer 402, as shown in FIG. 5B. In FIG. 5C, the fabrication process may continue with removing the remaining portions of the photoresist. The substrate 401 now includes the conductive channels 410 along with the first metal layer 402, the second metal layer 404 and the core 412. In FIG. 5D, the fabrication process may continue with conventional processing on substrate 401. For example, vias 408 are formed by drilling and filling or plating the holes to form the vias 408 between the first metal layer 402 and the second metal layer 404. Lithographic processes can be performed to pattern and etch the first metal layer 402, to form the signal interconnects 414, the adjacent grounds 406(1) and any other metal structure in the first metal layer 402. Likewise, the lithographic processes can be performed to pattern and etch the second metal layer 404, to form the ground plane portions 406(2) and any other metal structure in the first metal layer 402. It will be appreciated that the substrate 401 (in FIG. 5D) is similar to the substrate 101 (in FIG. 1) except it is rotated 180 degrees, with the first metal layer 402 on the bottom and the second metal layer 404 on top. Accordingly, a detailed discussion of the various aspects of the substrate 401 will not be provided.

Accordingly, it will be appreciated from the foregoing disclosure that additional processes for fabricating the various aspects disclosed herein will be apparent to those skilled in the art and a literal rendition of the each of the various processes will not be provided or illustrated in the included drawings. For example, it will be appreciated that in some aspects, the fabrication process for a coreless substrate can generally follow the fabrication process discussed above. Further, it will be appreciated that the sequence of the fabrication processes is not necessarily in any order and later processes may be discussed earlier for convenience of discussing the various aspects disclosed.

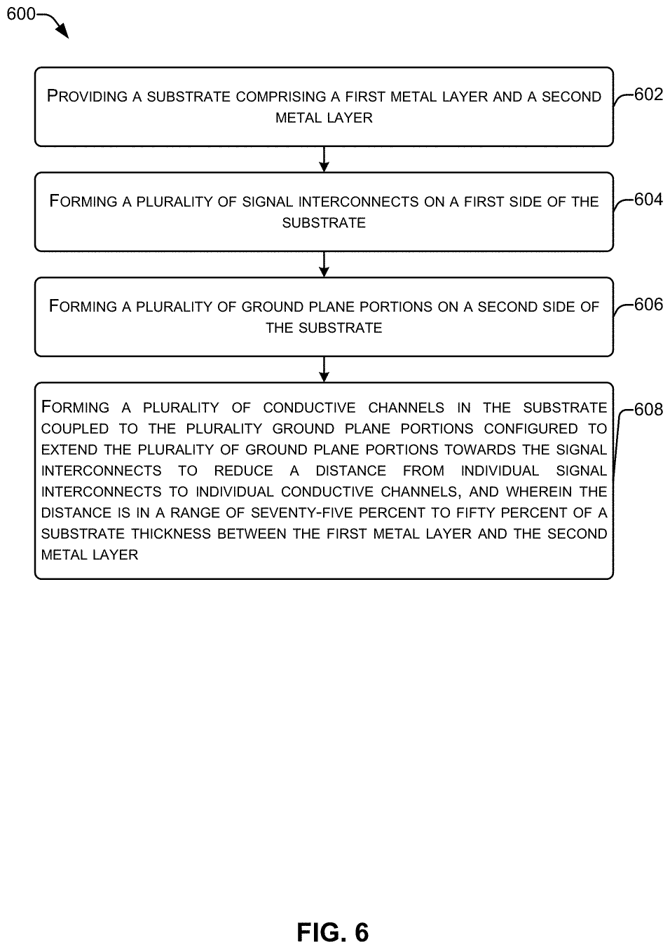

It will be appreciated from the foregoing that there are various methods for fabricating devices disclosed herein. FIG. 6 illustrates a flowchart of a method/process 600 for fabricating devices/apparatuses including a lower impedance substrate in accordance with at least one aspect of the disclosure. In the flow diagram of FIG. 6, each block represents one or more operations that can be implemented in hardware, software, or a combination thereof. In the context of software, the blocks represent computer-executable instructions that, when executed by one or more processors, cause the processors to perform the recited operations. The order in which the blocks are described is not intended to be construed as a limitation, and any number of the described operations can be combined in any order and/or in parallel to implement the processes. For discussion purposes, the process 600 is described with reference to FIGS. 1, 2, 3, 4A, 4B, 4C, 4D, 5A, 5B, 5C, and 5D as described above, although other models, configurations, systems, and environments may be used to implement the process. In some aspects, the process 600 may be performed in part during a semiconductor manufacturing process.

At block 602, the process 600 begins with providing a substrate comprising a first metal layer and a second metal layer. At block 604, the process 600 continues with forming a plurality of signal interconnects on a first side of the substrate. For example, in FIG. 5D, patterning is used to create the signal interconnects 114 or 214 in the first metal layer 102 or 202. At block 606, the process 600 continues with forming a plurality of ground plane portions on a second side of the substrate. For example, ground plane portions 106(2) or 206(2) in the first metal layer 102 or 202. At block 608, the process 600 continues with forming a plurality of conductive channels in the substrate coupled to the plurality of ground plane portions. The plurality of conductive channels is configured to extend the plurality of ground plane portions towards the signal interconnects to reduce a distance from individual signal interconnects to individual conductive channels. For example, in FIGS. 5A, 5B, and 5C, the conductive channels 410 are created and plated or filled with metal to create the conductive channels 410 that are in contact with ground plane portions (e.g., 406(2) in FIG. 5D). The individual conductive channels are located below individual signal interconnects. Further, in block 608, the distance in some aspects is in a range of seventy-five percent to fifty percent of a substrate thickness between the first metal layer and the second metal layer. For example, as illustrated in FIG. 1, each of the conductive channels 110 are located below one of the signal interconnects 114. The distance 118 from each of the conductive channels 110 to the signal interconnect 114 located directly above each conductive channel 110 is at least 25% less than the thickness 116 of the core 112 or can be considered to be 75% to 50% of the substrate thickness. For example, if the substrate thickness 116 of the core 112 is 40 microns, then the distance 118 between the signal interconnect 114 and the conductive channel located below the signal interconnect 114 is between about 20 to 30 microns, e.g., 50% to 25% of the thickness 116 of the core 112. As another example, in FIG. 2, each of the conductive channels 210 are located below one of the signal interconnects 214. The distance 218 from each of the conductive channels 210 to the signal interconnect 214 located directly above each conductive channel 210 is less than the 75% to 50% of the substrate thickness 216 of the substrate 201.

Thus, conductive channels that are in contact with a ground plane are placed in a substrate (e.g., cored, or coreless), beneath signal interconnects capable of carrying high-speed data, to provide the technical advantage of reducing the distance between the signal interconnects and the ground plane. The reduced distance provides a further technical advantage of a lower impedance. The lower impedance provides the technical advantage of enabling the signal interconnects to carry high-speed data signals, such as DQ signals used to access DRAM. In this way, the signal interconnects can be used to access faster DRAM (e.g., as compared to substrates that do not include the conductive channels), thereby enabling faster performance.

Other technical advantages will be recognized from various aspects disclosed herein and these technical advantages are merely provided as examples and should not be construed to limit any of the various aspects disclosed herein.

The foregoing disclosed devices and functionalities may be designed and stored in computer files (e.g., register-transfer level (RTL), Geometric Data Stream (GDS) Gerber, and the like) stored on computer-readable media. Some or all such files may be provided to fabrication handlers who fabricate devices based on such files. Resulting products may include various components, including semiconductor wafers that are then cut into semiconductor die and packaged into semiconductor packages, integrated devices, package on package devices, system-on-chip devices, and the like, which may then be employed in the various devices described herein.

It will be appreciated that various aspects disclosed herein can be described as functional equivalents to the structures, materials and/or devices described and/or recognized by those skilled in the art. For example, in one aspect, an apparatus may comprise a means for performing the various functionalities discussed above. It will be appreciated that the aforementioned aspects are merely provided as examples and the various aspects claimed are not limited to the specific references and/or illustrations cited as examples.

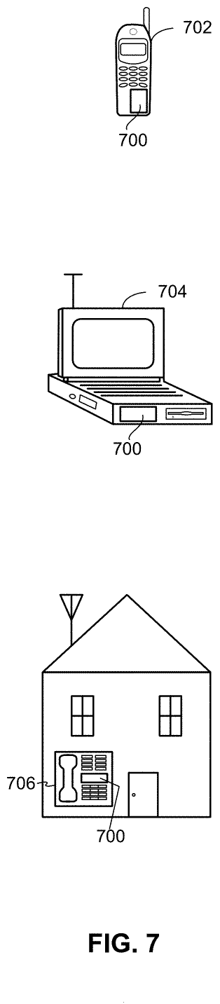

FIG. 7 illustrates various electronic devices that may be integrated with any of the aforementioned packages or semiconductor devices accordance with various examples of the disclosure. For example, a mobile phone device 702, a laptop computer device 704, and a fixed location terminal device 706 may each be considered generally user equipment (UE) and may include the package 700 with the cored substrate, as described herein. The package 700 may be, for example, any of the integrated circuits, dies, integrated devices, integrated device packages, integrated circuit devices, device packages, integrated circuit (IC) packages, package-on-package devices described herein. The devices 702, 704, 706 illustrated in FIG. 7 are merely exemplary. Other devices may also include the package 700 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices, servers, routers, electronic devices implemented in automotive vehicles (e.g., autonomous vehicles), an Internet of things (IoT) device or any other device that stores or retrieves data or computer instructions or any combination thereof.

It can be noted that, although particular frequencies, integrated circuits (ICs), hardware, and other features are described in the aspects herein, alternative aspects may vary. That is, alternative aspects may utilize additional or alternative frequencies (e.g., other the 60 GHz and/or 28 GHz frequency bands), antenna elements (e.g., having different size/shape of antenna element arrays), scanning periods (including both static and dynamic scanning periods), electronic devices (e.g., WLAN APs, cellular base stations, smart speakers, IoT devices, mobile phones, tablets, personal computer (PC), etc.), and/or other features. A person of ordinary skill in the art will appreciate such variations.

It should be understood that any reference to an element herein using a designation such as “first,” “second,” and so forth does not generally limit the quantity or order of those elements. Rather, these designations may be used herein as a convenient method of distinguishing between two or more elements or instances of an element. Thus, a reference to first and second elements does not mean that only two elements may be employed there or that the first element must precede the second element in some manner. Also, unless stated otherwise a set of elements may comprise one or more elements. In addition, terminology of the form “at least one of A, B, or C” or “one or more of A, B, or C” or “at least one of the group consisting of A, B, and C” used in the description or the claims means “A or B or C or any combination of these elements.” For example, this terminology may include A, or B, or C, or A and B, or A and C, or A and B and C, or 2A, or 2B, or 2C, and so on.

In view of the descriptions and explanations above, those of skill in the art will appreciate that the various illustrative logical blocks, modules, circuits, and algorithm steps described in connection with the aspects disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

In the detailed description above it can be seen that different features are grouped together in examples. This manner of disclosure should not be understood as an intention that the example clauses have more features than are explicitly mentioned in each clause. Rather, the various aspects of the disclosure may include fewer than all features of an individual example clause disclosed. Therefore, the following clauses should hereby be deemed to be incorporated in the description, wherein each clause by itself can stand as a separate example. Although each dependent clause can refer in the clauses to a specific combination with one of the other clauses, the aspect(s) of that dependent clause are not limited to the specific combination. It will be appreciated that other example clauses can also include a combination of the dependent clause aspect(s) with the subject matter of any other dependent clause or independent clause or a combination of any feature with other dependent and independent clauses. The various aspects disclosed herein expressly include these combinations, unless it is explicitly expressed or can be readily inferred that a specific combination is not intended (e.g., contradictory aspects, such as defining an element as both an insulator and a conductor). Furthermore, it is also intended that aspects of a clause can be included in any other independent clause, even if the clause is not directly dependent on the independent clause. Implementation examples are described in the following numbered clauses:

Clause 1. An apparatus comprising a substrate, the substrate comprising: a first metal layer comprising a plurality of signal interconnects on a first side of the substrate; a second metal layer comprising a plurality of ground plane portions on a second side of the substrate; and a plurality of conductive channels in the substrate coupled to the plurality of ground plane portions configured to extend the plurality of ground plane portions towards the signal interconnects to reduce a distance from individual signal interconnects to individual conductive channels, and wherein the distance is in a range of seventy-five percent to fifty percent of a substrate thickness between the first metal layer and the second metal layer.

Clause 2. The apparatus of clause 1, wherein the plurality of signal interconnects is configured to carry a high-speed data signal.

Clause 3. The apparatus of clause 2, wherein the plurality of signal interconnects is coupled to a dynamic random-access memory (DRAM).

Clause 4. The apparatus of clause 3, further comprising: a processor die, wherein the processor die is coupled to the DRAM by the substrate.

Clause 5. The apparatus of clause 4, further comprising: a molded embedded package (MEP) comprising the processor die, the substrate, and the DRAM.

Clause 6. The apparatus of any of clauses 1 to 5, wherein the first metal layer, the second metal layer and the plurality of conductive channels comprises at least one of: Copper (Cu), Cobalt (Co), Ruthenium (Ru), Wolfram (W), Molybdenum (Mo), Gold (Au), Silver (Ag), Aluminum (Al), Tin (Sn), or any combination thereof.

Clause 7. The apparatus of any of clauses 1 to 6, wherein the substrate is a cored substrate.

Clause 8. The apparatus of clause 7, wherein the substrate thickness is in a range of 40 micrometers to 1.2 millimeters.

Clause 9. The apparatus of any of clauses 7 to 8, wherein the plurality of conductive channels is formed in a core of the cored substrate, and wherein the substrate thickness is about 40 micrometers and the distance is between about 20 micrometers to about 30 micrometers.

Clause 10. The apparatus of any of clauses 1 to 9, wherein the substrate is a coreless substrate having a dielectric between the first metal layer and the second metal layer.

Clause 11. The apparatus of clause 10, wherein the substrate thickness is in a range of 25 micrometers to 50 micrometers.

Clause 12. The apparatus of any of clauses 10 to 11, wherein the plurality of conductive channels is formed in the dielectric of the coreless substrate, wherein the substrate thickness is about 25 micrometers, and the distance is between about 12.5 micrometers to about 19 micrometers.

Clause 13. The apparatus of any of clauses 1 to 12, wherein an impedance of each of the plurality of signal interconnects is less than 50 ohms.

Clause 14. The apparatus of any of clauses 1 to 13, wherein a width of each of plurality of conductive channels is no more than 5 micrometers wider than a width of each of the plurality of signal interconnects.

Clause 15. The apparatus of any of clauses 1 to 14, wherein the apparatus selected from the group consisting of: a package, a molded embedded package (MEP), a music player, a video player, an entertainment unit, a navigation device, a communications device, a mobile device, a mobile phone, a smartphone, a personal digital assistant, a fixed location terminal, a tablet computer, a computer, a wearable device, an Internet of things (IoT) device, a laptop computer, a server, a base station, and a device in an automotive vehicle.

Clause 16. A method of fabricating an apparatus, the method comprising: providing a substrate comprising a first metal layer and a second metal layer; forming a plurality of signal interconnects on a first side of the substrate; forming a plurality of ground plane portions on a second side of the substrate; and forming a plurality of conductive channels in the substrate coupled to the plurality of ground plane portions configured to extend the plurality of ground plane portions towards the signal interconnects to reduce a distance from individual signal interconnects to individual conductive channels, and wherein the distance in a range of seventy-five percent to fifty percent of a substrate thickness between the first metal layer and the second metal layer.

Clause 17. The method of clause 16, wherein the plurality of signal interconnects is configured to carry a high-speed data signal.

Clause 18. The method of clause 17, wherein the plurality of signal interconnects is coupled to a dynamic random-access memory (DRAM).

Clause 19. The method of clause 18, further comprising: coupling a processor die to the DRAM using the substrate.

Clause 20. The method of clause 19, further comprising: forming a molded embedded package (MEP) comprising the processor die, the substrate, and the DRAM.

Clause 21. The method of any of clauses 16 to 20, wherein the first metal layer, the second metal layer and the plurality of conductive channels comprises at least one of: Copper (Cu), Cobalt (Co), Ruthenium (Ru), Wolfram (W), Molybdenum (Mo), Gold (Au), Silver (Ag), Aluminum (Al), Tin (Sn), or any combination thereof.

Clause 22. The method of any of clauses 16 to 21, wherein the substrate is a cored substrate having a core.

Clause 23. The method of clause 22, wherein the substrate thickness is in a range of 40 micrometers to 1.2 millimeters.

Clause 24. The method of clause 23, wherein the plurality of conductive channels is formed in the core of the cored substrate, and wherein the substrate thickness is about 40 micrometers and the distance is between about 20 micrometers to about 30 micrometers.

Clause 25. The method of any of clauses 16 to 24, wherein the substrate is a coreless substrate having a dielectric between the first metal layer and the second metal layer.

Clause 26. The method of clause 25, wherein the substrate thickness is in a range of 25 micrometers to 50 micrometers.

Clause 27. The method of any of clauses 25 to 26, wherein the plurality of conductive channels is formed in the dielectric of the coreless substrate, wherein the substrate thickness is about 25 micrometers, and the distance is between about 12.5 micrometers to about 19 micrometers.

Clause 28. The method of any of clauses 16 to 27, wherein an impedance of each of the plurality of signal interconnects is less than 50 ohms.

Clause 29. The method of any of clauses 16 to 28, wherein a width of each of plurality of conductive channels is no more than 5 micrometers wider than a width of each of the plurality of signal interconnects.

Clause 30. The method of any of clauses 16 to 29, wherein the apparatus is selected from the group consisting of: a package, a molded embedded package (MEP), a music player, a video player, an entertainment unit, a navigation device, a communications device, a mobile device, a mobile phone, a smartphone, a personal digital assistant, a fixed location terminal, a tablet computer, a computer, a wearable device, an Internet of things (IoT) device, a laptop computer, a server, a base station, and a device in an automotive vehicle.

It will be appreciated, for example, that an apparatus or any component of an apparatus may be configured to (or made operable to or adapted to) provide functionality as taught herein. This may be achieved, for example: by manufacturing (e.g., fabricating) the apparatus or component so that it will provide the functionality; by programming the apparatus or component so that it will provide the functionality; or through the use of some other suitable implementation technique. As one example, an integrated circuit may be fabricated to provide the requisite functionality. As another example, an integrated circuit may be fabricated to support the requisite functionality and then configured (e.g., via programming) to provide the requisite functionality. As yet another example, a processor circuit may execute code to provide the requisite functionality

Moreover, the methods, sequences, and/or algorithms described in connection with the aspects disclosed herein may be embodied directly in hardware, in a software module executed by a processor, or in a combination of the two. A software module may reside in random access memory (RAM), flash memory, read-only memory (ROM), erasable programmable ROM (EPROM), electrically erasable programmable ROM (EEPROM), registers, hard disk, a removable disk, a CD-ROM, or any other form of storage medium known in the art. An example storage medium is coupled to the processor such that the processor can read information from, and write information to, the storage medium. In the alternative, the storage medium may be integral to the processor (e.g., cache memory).

While the foregoing disclosure shows various illustrative aspects, it should be noted that various changes and modifications may be made to the illustrated examples without departing from the scope defined by the appended claims. The present disclosure is not intended to be limited to the specifically illustrated examples alone. For example, unless otherwise noted, the functions, steps, and/or actions of the method claims in accordance with the aspects of the disclosure described herein need not be performed in any particular order. Furthermore, although certain aspects may be described or claimed in the singular, the plural is contemplated unless limitation to the singular is explicitly stated.

What is claimed is:

1. An apparatus comprising a substrate, the substrate comprising:
a first metal layer comprising a plurality of signal interconnects on a first side of the substrate;
a second metal layer comprising a plurality of ground plane portions on a second side of the substrate; and
a plurality of conductive channels in the substrate coupled to the plurality of ground plane portions configured to extend the plurality of ground plane portions towards the signal interconnects to reduce a distance from individual signal interconnects to individual conductive channels, and wherein the distance is in a range of seventy-five percent to fifty percent of a substrate thickness between the first metal layer and the second metal layer.

2. The apparatus of claim 1, wherein the plurality of signal interconnects is configured to carry a high-speed data signal.

3. The apparatus of claim 2, wherein the plurality of signal interconnects is coupled to a dynamic random-access memory (DRAM).

4. The apparatus of claim 3, further comprising:
a processor die, wherein the processor die is coupled to the DRAM by the substrate.

5. The apparatus of claim 4, further comprising:
a molded embedded package (MEP) comprising the processor die, the substrate, and the DRAM.

6. The apparatus of claim 1, wherein the first metal layer, the second metal layer and the plurality of conductive channels comprises at least one of: Copper (Cu), Cobalt (Co), Ruthenium (Ru), Wolfram (W), Molybdenum (Mo), Gold (Au), Silver (Ag), Aluminum (Al), Tin (Sn), or any combination thereof.

7. The apparatus of claim 1, wherein the substrate is a cored substrate.

8. The apparatus of claim 7, wherein the substrate thickness is in a range of 40 micrometers to 1.2 millimeters.

9. The apparatus of claim 7, wherein the plurality of conductive channels is formed in a core of the cored substrate, and wherein the substrate thickness is about 40 micrometers, and the distance is between about 20 micrometers to about 30 micrometers.

10. The apparatus of claim 1, wherein the substrate is a coreless substrate having a dielectric between the first metal layer and the second metal layer.

11. The apparatus of claim 10, wherein the substrate thickness is in a range of 25 micrometers to 50 micrometers.

12. The apparatus of claim 10, wherein the plurality of conductive channels is formed in the dielectric of the coreless substrate, wherein the substrate thickness is about 25 micrometers, and the distance is between about 12.5 micrometers to about 19 micrometers.

13. The apparatus of claim 1, wherein an impedance of each of the plurality of signal interconnects is less than 50 ohms.

14. The apparatus of claim 1, wherein a width of each of plurality of conductive channels is no more than 5 micrometers wider than a width of each of the plurality of signal interconnects.

15. The apparatus of claim 1, wherein the apparatus selected from the group consisting of: a package, a molded embedded package (MEP), a music player, a video player, an entertainment unit, a navigation device, a communications device, a mobile device, a mobile phone, a smartphone, a personal digital assistant, a fixed location terminal, a tablet computer, a computer, a wearable device, an Internet of things (IoT) device, a laptop computer, a server, a base station, and a device in an automotive vehicle.

16. A method of fabricating an apparatus, the method comprising:
providing a substrate comprising a first metal layer and a second metal layer;
forming a plurality of signal interconnects on a first side of the substrate;
forming a plurality of ground plane portions on a second side of the substrate; and
forming a plurality of conductive channels in the substrate coupled to the plurality of ground plane portions configured to extend the plurality of ground plane portions towards the signal interconnects to reduce a distance from individual signal interconnects to individual conductive channels, and wherein the distance is in a range of seventy-five percent to fifty percent of a substrate thickness between the first metal layer and the second metal layer.

17. The method of claim 16, wherein the plurality of signal interconnects is configured to carry a high-speed data signal.

18. The method of claim 17, wherein the plurality of signal interconnects is coupled to a dynamic random-access memory (DRAM).

19. The method of claim 18, further comprising:
coupling a processor die to the DRAM using the substrate.

20. The method of claim 19, further comprising:
forming a molded embedded package (MEP) comprising the processor die, the substrate, and the DRAM.

21. The method of claim 16, wherein the first metal layer, the second metal layer and the plurality of conductive channels comprises at least one of: Copper (Cu), Cobalt (Co), Ruthenium (Ru), Wolfram (W), Molybdenum (Mo), Gold (Au), Silver (Ag), Aluminum (Al), Tin (Sn), or any combination thereof.

22. The method of claim 16, wherein the substrate is a cored substrate having a core.

23. The method of claim 22, wherein the substrate thickness is in a range of 40 micrometers to 1.2 millimeters.

24. The method of claim 23, wherein the plurality of conductive channels is formed in the core of the cored substrate, and wherein the substrate thickness is about 40 micrometers, and the distance is between about 20 micrometers to about 30 micrometers.

25. The method of claim 16, wherein the substrate is a coreless substrate having a dielectric between the first metal layer and the second metal layer.

26. The method of claim 25, wherein the substrate thickness is in a range of 25 micrometers to 50 micrometers.

27. The method of claim 25, wherein the plurality of conductive channels is formed in the dielectric of the coreless substrate, wherein the substrate thickness is about 25 micrometers, and the distance is between about 12.5 micrometers to about 19 micrometers.

28. The method of claim 16, wherein an impedance of each of the plurality of signal interconnects is less than 50 ohms.

29. The method of claim 16, wherein a width of each of plurality of conductive channels is no more than 5 micrometers wider than a width of each of the plurality of signal interconnects.

30. The method of claim 16, wherein the apparatus is selected from the group consisting of: a package, a molded embedded package (MEP), a music player, a video player, an entertainment unit, a navigation device, a communications device, a mobile device, a mobile phone, a smartphone, a personal digital assistant, a fixed location terminal, a tablet computer, a computer, a wearable device, an Internet of things (IoT) device, a laptop computer, a server, a base station, and a device in an automotive vehicle.
